(19) United States
(12) Patent Application Publication
(10) Pub. No.: US 2025/0351680 A1
(43) Pub. Date: Nov. 13, 2025

(54) DISPLAY PANEL, METHOD FOR MANUFACTURING DISPLAY PANEL, AND ELECTRONIC DEVICE

(71) Applicants: Hefei Visionox Technology Co., Ltd., Hefei (CN); Visionox Technology Inc., Jiangsu (CN)

(72) Inventors: Liusong NI, Hefei (CN); Chung-Chun LEE, Hefei (CN); Yi-Yu LAI, Hefei (CN); Jen-Yu LEE, Hefei (CN); Bowen YANG, Hefei (CN); Zhenhai YUE, Hefei (CN)

(73) Assignees: Hefei Visionox Technology Co., Ltd., Hefei (CN); Visionox Technology Inc., Jiangsu (CN)

(21) Appl. No.: 18/895,639

(22) Filed: Sep. 25, 2024

(30) Foreign Application Priority Data
May 10, 2024 (CN) 202410579969.2

(51) Int. Cl. H10K 59/122; H10K 59/12; H10K 59/80

(52) U.S. Cl. CPC H10K 59/122; H10K 59/1201; H10K 59/873

(57) ABSTRACT

A display panel and an electronic device, and relate to the field of the display technology. In the display panel, the isolation structure has a sidewall facing the isolation opening, a first angle is formed between the sidewall and the base plate, the first electrode of the light-emitting device contacts the sidewall, the first electrode includes a first end portion, the isolation structure includes a second end portion, the second end portion extends from the sidewall to an isolation opening corresponding to the first end portion in a direction away from the first end portion, a second angle is formed between the base plate and a connecting line from the first end portion to the second end portion, and the first angle is less than a complementary angle of the second angle.

### CROSS REFERENCE TO RELATED APPLICATION

The present application claims priority to Chinese Patent Application No. 202410579969.2 filed on May 10, 2024, and titled “DISPLAY PANEL, METHOD FOR MANUFACTURING DISPLAY PANEL, AND ELECTRONIC DEVICE”, which is incorporated herein by reference in its entirety.

### TECHNICAL FIELD

The present application relates to the field of display technology, and particularly to a display panel, a method for manufacturing a display panel, and an electronic device.

### BACKGROUND

With the development of display technology, consumers have higher and higher requirements for the display, and for this reason, the requirements for the manufacturing process of the display panel are also more and more strict. Therefore, how to ensure the yield of the display panel under the strict requirements for the manufacturing process is a technical problem urgently required to be solved by those skilled in the art.

### SUMMARY

In order to overcome the technical problem mentioned in the above background, embodiments of the present application provide a display panel, a method for manufacturing a display panel, and an electronic device.

In a first aspect of the present application, there is provided a display panel, including:
a base plate;
an isolation structure, the isolation structure being located on the base plate, enclosing and forming a plurality of isolation openings, and having a sidewall facing the isolation opening, and a first angle being formed between the sidewall and the base plate;
a plurality of light-emitting devices, the light-emitting device being located in the isolation opening and including a first electrode contacted with the sidewall;
in which on a first normal section of the display panel, the first electrode includes a first end portion, the isolation structure includes a second end portion, the second end portion extends from the sidewall to an isolation opening corresponding to the first end portion in a direction away from the first end portion, a second angle is formed between the base plate and a connecting line from the first end portion to the second end portion, and the first angle is less than a complementary angle of the second angle.

In a second aspect of the present application, there is further provided a method for manufacturing a display panel, including:
providing a base plate;
preparing an isolation structure layer on the base plate, and patterning the isolation structure layer to obtain an isolation structure and a plurality of isolation openings enclosed and formed by the isolation structure, in which the isolation structure has a sidewall facing the isolation opening, and a first angle is formed between the sidewall and the base plate; and
forming a light-emitting device in the isolation opening by evaporation, to contact a first electrode of the light-emitting device with the sidewall, in which the first angle is less than a complementary angle of an evaporation angle of the first electrode.

In a third aspect of the present application, there is further provided an electronic device, including the display panel according to any of the possible implementations in the first aspect.

The embodiments of the present application provide the display panel, the method for manufacturing the display panel, and the electronic device. In the display panel, the isolation structure has a sidewall facing the isolation opening, a first angle is formed between the sidewall and the base plate, the first electrode of the light-emitting device contacts the sidewall, the first electrode includes a first end portion, the isolation structure includes a second end portion, the second end portion extends from the sidewall to an isolation opening corresponding to the first end portion in a direction away from the first end portion, a second angle is formed between the base plate and a connecting line from the first end portion to the second end portion, and the first angle is less than a complementary angle of the second angle. The above design can avoid the situation of the minimum coverage area of the first electrode on the sidewall, so as to increase the contact area of the first electrode on the sidewall, which ensures the contact effect of the first electrode, thereby improving the product yield of the display panel.

### BRIEF DESCRIPTION OF THE DRAWINGS

The drawings required to describe embodiments of the present application are introduced briefly below to illustrate technical solutions of the embodiments of the present application more clearly. It should be understood that the drawings described below only show some embodiments of the present application, and thus should not be regarded as a limitation of the scope. For those skilled in the art, other related drawings may be obtained from these drawings without inventive efforts.

FIG. 1 shows a first schematic partial diagram of a display panel on a first normal section according to an embodiment of the present application;

FIG. 2 shows a diagram of a positional relationship between the isolation structure and the isolation opening shown in FIG. 1;

FIG. 3 shows a schematic enlarged partial diagram of an isolation structure according to an embodiment of the present application;

FIG. 4 shows a second schematic partial diagram of a display panel on a first normal section according to an embodiment of the present application;

FIG. 5 shows a third schematic partial diagram of a display panel on a first normal section according to an embodiment of the present application;

FIG. 6 shows a schematic illustration of the coverage of the deposited material on the sidewall at different first angles according to an embodiment of the present application;

FIG. 7 shows a fourth schematic partial diagram of a display panel on a first normal section according to an embodiment of the present application;

FIG. 8 shows a fifth schematic partial diagram of a display panel on a first normal section according to an embodiment of the present application;

FIG. 9 shows a sixth schematic partial diagram of a display panel on a first normal section according to an embodiment of the present application;

FIG. 10 shows a seventh schematic partial diagram of a display panel on a first normal section according to an embodiment of the present application;

FIG. 11 shows a schematic structural diagram of a film layer of a light-emitting device according to an embodiment of the present embodiment;

FIG. 12 shows another schematic structural diagram of a film layer of a light-emitting device according to an embodiment of the present embodiment;

FIG. 13 shows an eighth schematic partial diagram of a display panel on a first normal section according to an embodiment of the present application;

FIG. 14 shows a ninth schematic partial diagram of a display panel on a first normal section according to an embodiment of the present application;

FIG. 15 shows a tenth schematic partial diagram of a display panel on a first normal section according to an embodiment of the present application;

FIG. 16 shows a schematic flow diagram of a method for manufacturing a display panel according to an embodiment of the present application.

Reference numerals: 1-display panel; 11-base plate; 12-isolation structure; 12a-sidewall; 12b-base plane; 121-isolation opening; 122-first isolation portion; 122a-first surface; 123-second isolation portion; 124-adhesive portion; 124a-second surface; 13-light-emitting device; 131-first electrode; 132-light-emitting material layer; 1321-hole injection layer; 1322-hole transport layer; 1324-emission layer; 1325-hole block layer; 1326-electron transport layer; 1327-electron injection layer; 133-second electrode; 14-pixel definition layer; 141-pixel opening; 151-first encapsulation layer; 1511-encapsulation unit; 152-second encapsulation layer; 153-third encapsulation layer.

### DETAILED DESCRIPTION

In order to make objects, technical solutions and advantages of the embodiments of the present application clearer, the technical solutions in the embodiments of the present application will be described clearly and completely in conjunction with the accompanying drawings for the embodiments of the present application. Obviously, the described embodiments are merely a part of and not all of the embodiments of the present application. The components in the embodiments of the present application generally described and shown in the accompanying drawings herein can be arranged and designed in various different configurations.

In the description of the present application, it should be noted that orientational or positional relationships indicated by the terms “upper”, “lower”, and the like are orientational or positional relationships as shown in the accompanying drawings or orientational or positional relationships with which the product of the present application is placed commonly when in use, which are merely to facilitate and simplify the description of the present application, rather than to indicate or imply that the referenced components or elements must have such a particular orientation, or must be constructed and operated in such a particular orientation and thus should not be considered as limitations intended to the present application.

In some display panels, in order to reduce a difficulty of an evaporation process for a light-emitting material, an isolation structure is provided on a pixel definition layer between pixel openings. In evaporation of a whole layer of a light-emitting material layer and a whole layer of a first electrode, the light-emitting material layer and the first electrode between adjacent pixel openings can be separated at the location of the isolation structure. By multiple evaporation processes and multiple etching processes, light-emitting device film layers can be formed in the respective pixel openings corresponding to light-emitting devices of different colors.

For the related contents of the isolation structure, reference can be made to patent applications No. PCT/CN2023/134518, CN 202310759370.2, CN 202310740412.8, CN 202310707209.0, CN 202311499823.9, CN 202310692671.8, CN 202311091555.7, CN 202311764506.5, CN 202310731471.9, CN 202310773656.6, and CN 202311346196.5, the contents of which are incorporated herein by reference.

In the above-mentioned panels, the first electrode contacts the isolation structure to obtain a power supply signal (such as an ELVSS signal), and a poor contact between the first electrode and the isolation structure may cause such a display panel to have a poor display problem such as a dark spot or a black spot, thereby resulting in a low yield of the display panel.

In order to solve the above problem, the inventors have inventively designed the following technical solutions, and specific implementations of the present application will be described in detail below in conjunction with the accompanying drawings. It should be noted that the above-discussed defects existing in the solution in the related art are founded by the inventors after practices and careful studies. Therefore, both the process of finding the technical problem and the solutions proposed below in the embodiments for the problem shall be contributions made by the inventors to the present application in the course of invention and should not be understood as technical contents commonly known to those skilled in the art.

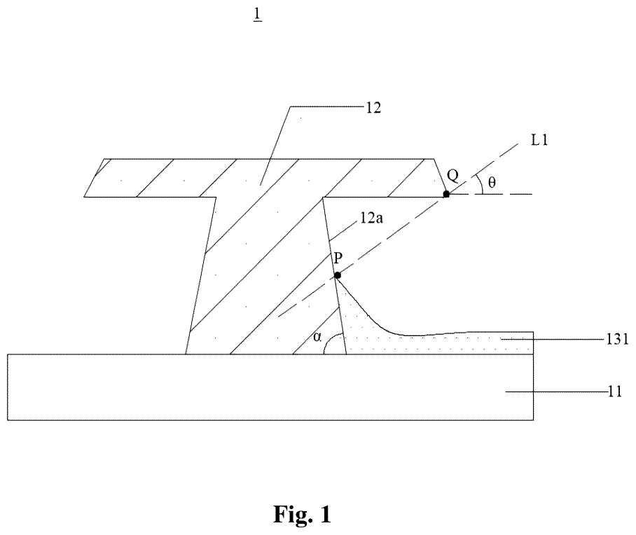

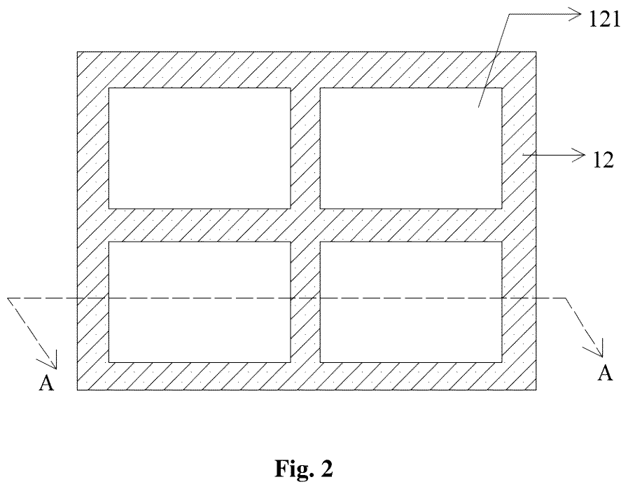

Referring to FIGS. 1 and 2, FIG. 1 shows a schematic partial diagram of a display panel on a first normal section according to an embodiment of the present application, and FIG. 2 shows a diagram of a positional relationship between an isolation structure and an isolation opening in an embodiment of the present application. In this embodiment, the display panel 1 includes a base plate 11, an isolation structure 12, and a light-emitting device. The base plate 11 includes a plurality of film layers, and includes at least a plurality of electrically conductive layers (such as metal layers) and an insulating layer located between adjacent electrically conductive layers, and a pixel drive circuit for providing a drive signal for the light-emitting device is formed in the base plate 11.

The isolation structure 12 is located on the base plate 11, and encloses and forms a plurality of isolation openings 121 on the base plate 11. The isolation structure 12 has a sidewall 12a facing the isolation opening 121, and a first angle α is formed between the sidewall 12a and the base plate 11, i.e., a first angle α is formed between the sidewall 12a and a bottom surface of the isolation structure 12 facing the base plate 11.

The light-emitting device is located in the isolation opening 121 and includes a first electrode 131, and the first electrode 131 contacts the sidewall 12a. The isolation structure 12 may connect first electrodes 131 of different light-emitting devices together, so as to provide the same power supply voltage to the first electrodes 131 of different light-emitting devices through the isolation structure 12.

On a first normal section of the display panel 1, the first electrode 131 includes a first end portion P, and the isolation structure 12 includes a second end portion Q, in which the first normal section may be a section perpendicular to a plane in which the base plate 11 is located and along a direction of a connecting line between two adjacent isolation openings 121 (the direction AA in FIG. 2), and the second end portion Q extends from the sidewall 12a to an isolation opening corresponding to the first end portion P in a direction away from the first end portion P. The first end portion P and the second end portion Q are located at the same side of the same isolation opening 121, the first end portion P corresponds to the highest contact position of the first electrode 131 on the sidewall 12a, and the second end portion Q is a part closest to the center of the isolation opening or a part corresponding to an edge of an orthographic projection of the isolation structure 12 on the base plate 11.

A second angle θ is formed between the base plate 11 and a connecting line L1 from the first end portion P to the second end portion Q, the second angle θ corresponds to an evaporation angle when the first electrode 131 is evaporated, and in this embodiment, the first angle α is less than a complementary angle (90−θ) of the second angle.

In the above structure, the first angle α is less than the complementary angle (90−θ) of the second angle, which can avoid the situation of the minimum coverage area of the first electrode 131 on the sidewall 12a, so as to increase the contact area of the first electrode 131 on the sidewall 12a, which ensures the contact effect of the first electrode 131, thereby improving the product yield of the display panel 1.

Further, in order to continuously form the first electrode 131 on the sidewall 12a and ensure the contact effect of the first electrode 131 on the sidewall 12a, the sidewall 12a is a smooth sidewall. Herein, the smooth sidewall means the surface of the sidewall 12a is relatively flat, and the relief difference of the surface is not great.

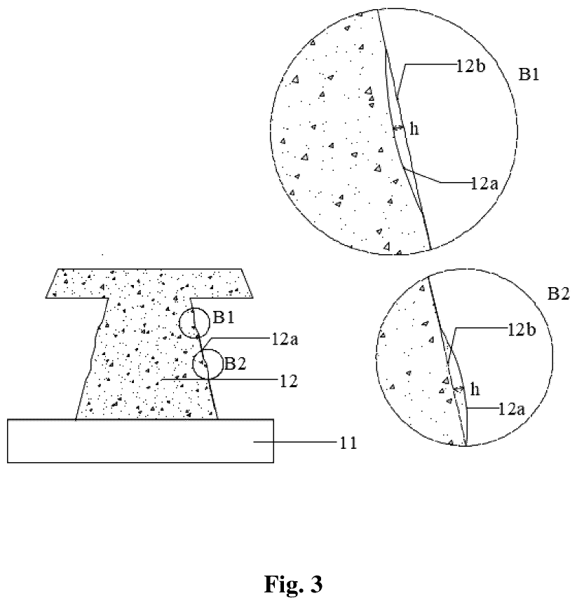

Referring to FIG. 3, the isolation structure 12 has a base surface 12b, in which base surface 12b satisfies: points at positions on the surface of the sidewall 12a are located at opposite sides of the base surface 12b as much as possible, and the distances from the points to the base surface 12b are minimal. The sidewall 12a has a certain relief height with respect to the base plane 12b. In this embodiment, a maximum relief height of the sidewall 12a with respect to the base surface 12b is not greater than 10 nm. As shown in the enlarged partial diagrams of the area B1 and the area B2 in FIG. 3, both a maximum height h of the recessed sidewall 12a with respect to the base surface 12b and a maximum height h of the protruding sidewall 12a with respect to the base surface 12b are not greater than 10 nm. Exemplarily, the maximum relief height of the sidewall 12a with respect to the base surface 12b may be not greater than any of 10 nm, 9.6 nm, 8.9 nm, 8.2 nm, 7.1 nm, 6.6 nm, 5.3 nm, 4.2 nm, 3.6 nm, 3.1 nm, 2.6 nm, 1.6 nm, or 1 nm.

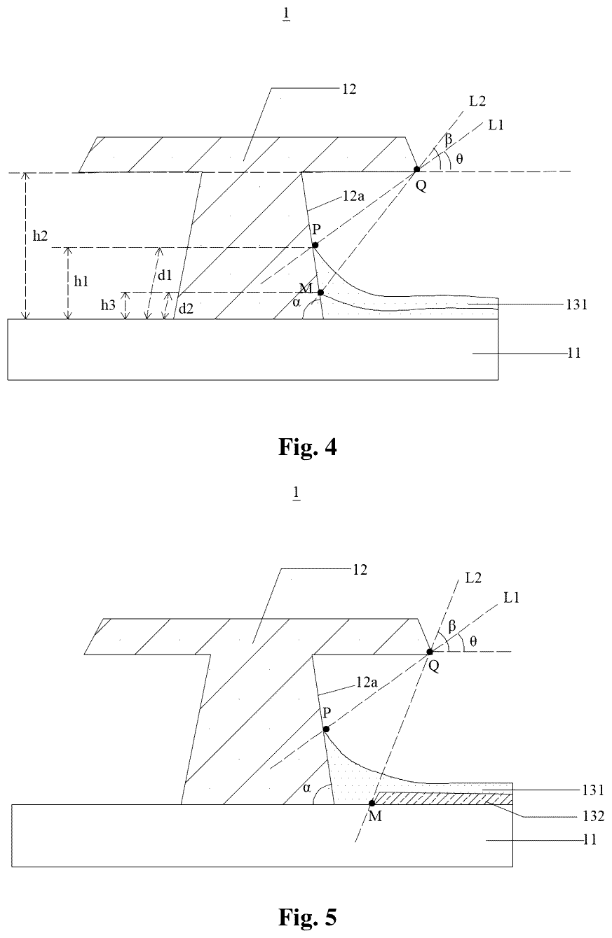

Further, referring to FIGS. 4 and 5, the light-emitting device further includes a light-emitting material layer 132 located at a side of the first electrode 131 facing the base plate 11, and on the first normal section, the light-emitting material layer 132 includes a third end portion M, in which the light-emitting material layer 132 may or may not contact the sidewall 12a. As shown in FIG. 5, under a condition that the light-emitting material layer 132 does not contact the sidewall 12a, an interval is formed between the light-emitting material layer 132 and the sidewall 12a, and the third end portion M corresponds to a part of the light-emitting material layer 132 closest to the isolation structure 12. As shown in FIG. 4, under a condition that the light-emitting material layer 132 contacts the sidewall 12a, the third end portion M corresponds to a part of the light-emitting material layer 132 at the highest contact position on the sidewall 12a of the isolation structure 12.

With further reference to FIG. 4, on the first normal section, the first end portion P extends a first length d1 on the sidewall 12a, the third end portion M extends a second length d2 on the sidewall 12a, and the first length d1 is greater than the second length d2, so as to ensure that the first electrode 131 effectively contacts the sidewall. A first perpendicular distance h1 is formed between the first end portion P and the base plate 11, a second perpendicular distance h2 is formed between the second end portion Q and the base plate 11, and a third perpendicular distance h3 is formed between the third end portion M and the base plate 11, in which the first perpendicular distance h1 is less than the second perpendicular distance h2, and the first perpendicular distance h1 is greater than the third perpendicular distance h3.

A third angle β is formed between the base plate 11 and a connecting line L2 from the third end portion M to the second end portion Q, and the third angle β may characterize an evaporation angle of the light-emitting material layer 132, in which the third angle β is greater than the second angle θ, i.e., the evaporation angle for evaporating the light-emitting material layer 132 is greater than the evaporation angle for evaporating the first electrode 131. This may ensure that an evaporation height of the light-emitting material layer 132 on the sidewall 12a is less than an evaporation height of the first electrode 131 on the sidewall 12a, ensuring that the first electrode 131 effectively contacts the sidewall 12a.

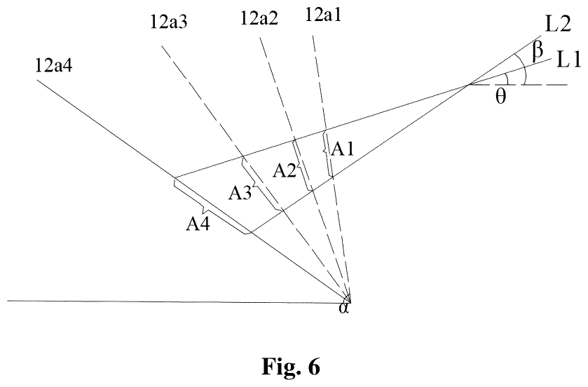

Referring to FIG. 6, the effective contact area of the first electrode 131 on the sidewall 12a is analyzed below with reference to the accompanying drawing. Under a condition that the first angle α and the second angle θ are complementary angles to each other, i.e., under a condition that an evaporation direction of the first electrode 131 is perpendicular to the sidewall 12a, an evaporation area of the first electrode 131 on the sidewall 12a is minimum. For example, both the light-emitting material layer 132 and the first electrode 131 are evaporated on the sidewall 12a. Based on the above relationship, as shown in FIG. 6, contact areas of the light-emitting material layer 132 and the first electrode 131 on the sidewall 12a may be changed by adjusting the angle α, thereby changing the effective contact section of the first electrode 131 on the sidewall 12a. Exemplarily, as shown in FIG. 6, an angle α of the sidewall 12a1, an angle α of the sidewall 12a2, an angle α of the sidewall 12a3, and an angle α of the sidewall 12a4 are reduced gradually, an effective contact area of the first electrode 131 on the sidewall 12a1 is A1, an effective contact area of the first electrode 131 on the sidewall 12a2 is A2, an effective contact area of the first electrode 131 on the sidewall 12a3 is A3, and an effective contact area of the first electrode 131 on the sidewall 12a4 is A4, and A1<A2<A3<A4, in which the effective contact area refers to an area where the first electrode 131 directly contacts the sidewall 12a. It can be seen from FIG. 6 that the less the angle α, the greater the effective contact area. Under a condition that the first angle α is equal to the complementary angle of the second angle θ, the coverage area of the first electrode 131 on the sidewall 12a is minimum; and under a condition that the first angle α is equal to the complementary angle of the third angle β, the coverage area of the light-emitting material layer 132 on the sidewall 12a is minimum.

In this embodiment, the first angle α is less than the complementary angle of the second angle θ, which can avoid the situation of the minimum coverage area of the first electrode 131 on the sidewall 12a, and reduce the coverage area of the deposited light-emitting material layer 132 on the sidewall 12a, so as to increase the effective contact area of the first electrode 131 on the sidewall 12a, which ensures the contact effect of the first electrode 131, thereby improving the product yield of the display panel.

In this embodiment, the first angle α is greater than 0 degrees, and the first angle α is less than 90 degrees. As shown in FIG. 6, under a condition that the first angle α is too great, the effective contact area A is relatively small, and under a condition that the first angle α is too small, on the one hand, an isolation structure having an undercut structure is less likely to be formed by etching, and on the other hand, the size of the isolation structure 12 may be increased, which reduces the ratio of the pixel opening. To overcome the above technical problem, the first angle α may range from 30 degrees to 80 degrees. Exemplarily, the first angle α may include 30 degrees, 33 degrees, 37 degrees, 45 degrees, 53 degrees, 60 degrees, 65 degrees, 70degrees, 73 degrees, 78 degrees, 80 degrees, etc.

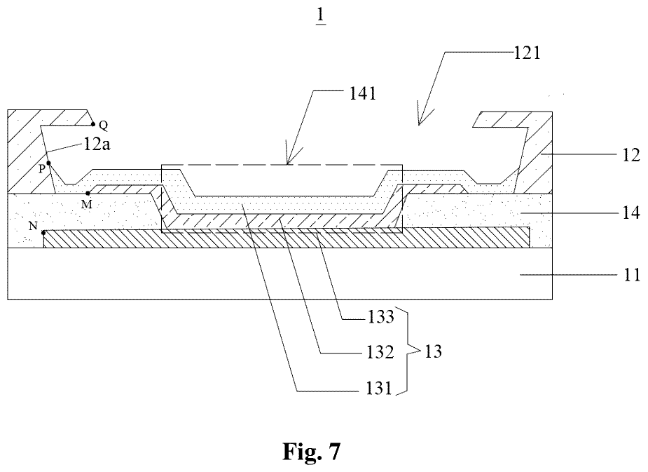

In one possible implementation, referring to FIG. 7, the display panel 1 further includes a pixel definition layer 14 located at one side of the base plate 11, and the isolation structure 12 is located at a side of the pixel definition layer 14 away from the base plate 11. The pixel definition layer 14 defines a pixel opening 141 on the base plate 11, the light-emitting device 13 is at least partially located in the pixel opening 141, the pixel opening 141 is connected with the isolation opening 121, and an orthographic projection of the pixel opening 141 on the base plate 11 is located within an orthographic projection of the isolation opening 121 on the base plate 11.

Further, with further reference to FIG. 7, the light-emitting device 13 further includes a second electrode 133 located at a side of the first electrode 131 facing the base plate 11, and in a direction away from the base plate 11, the second electrode 133, the light-emitting material layer 132, and the first electrode 131 are stacked in sequence. Exemplarily, the second electrode 133 may be an anode of the light-emitting device 13, and the first electrode 131 may be a cathode of the light-emitting device 13.

On the first normal section, the second electrode 133 has a fourth end portion N extending towards the first end portion P, and the fourth end portion N is located between the pixel definition layer 13 and the base plate 11.

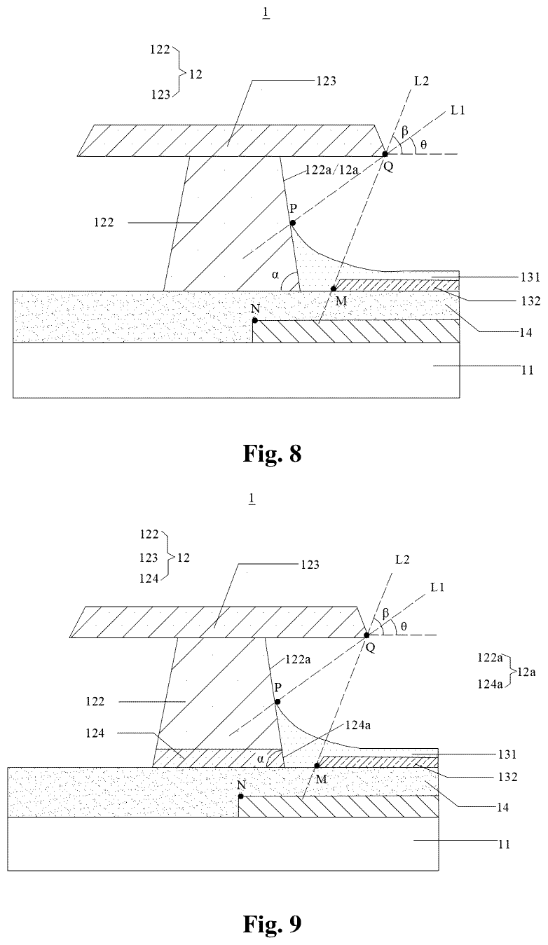

Further, referring to FIG. 8, the isolation structure 12 includes a first isolation portion 122 and a second isolation portion 123, and in a direction away from the base plate 11, the first isolation portion 122 and the second isolation portion 123 are stacked in sequence. The first isolation portion 122 has a first surface 122a facing the isolation opening 121, the first surface 122a is located in the sidewall 12a, the first electrode 131 contacts the first surface 122a, and the first end portion P is an end portion of the first electrode 131 contacting the first surface 122a. An orthographic projection of the first isolation portion 122 on the base plate 11 is located within an orthographic projection of the second isolation portion 123 on the base plate 11, the second isolation portion 123 may protrude from the first isolation portion 122 to the isolation opening, the second end portion Q is located on the second isolation portion 123, and the second end portion Q is the furthest end to which the second isolation portion 123 protrudes from the first isolation portion 122. An orthographic projection of the fourth end portion N on the base plate 11 is located within the orthographic projection of the first isolation portion 122 on the base plate 11. The pixel definition layer in the isolation opening 121 may not recessed, and the deposited first electrode 131 is evenly distributed, which ensures the contact yield. On the first normal section, the isolation structure 12 has a T-shaped section, in which the T-shaped structure may separate the deposited film layers, so that independent film layers can be formed in different isolation openings 121.

In one possible implementation, referring to FIG. 9, the isolation structure 12 further includes an adhesive portion 124, the adhesive portion 124 is located at a side of the first isolation portion 122 facing the base plate 11, and in a direction away from the base plate, the adhesive portion 124, the first isolation portion 122, and the second isolation portion 123 are stacked. The adhesive portion 124 has a second surface 124a facing the isolation opening 121, the first surface 122a and the second surface 124a are coplanar, and are located in the sidewall 12a. In this embodiment, on the first normal section, the isolation structure 12 has a T-shaped section, and the first electrode 131 contacts the first surface 122a and the second surface 124a.

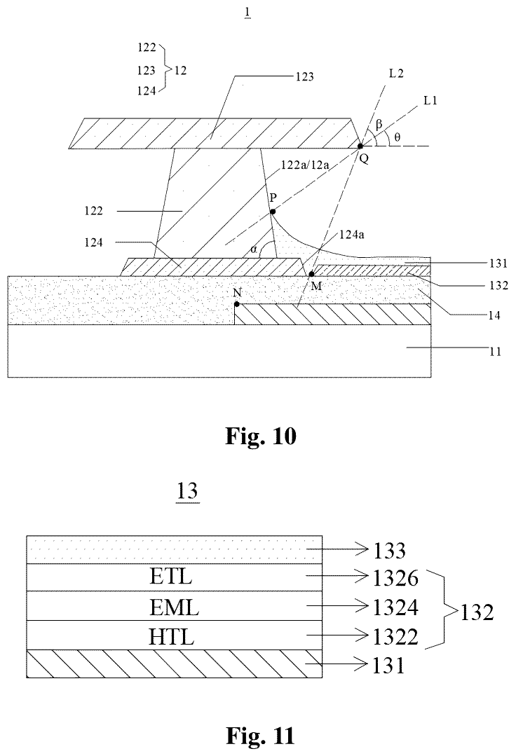

In another possible implementation, referring to FIG. 10, the isolation structure 12 further includes the adhesive portion 124, the adhesive portion 124 is located at the side of the first isolation portion 122 facing the base plate 11, and in the direction away from the base plate 11, the adhesive portion 124, the first isolation portion 122, and the second isolation portion 123 are stacked. The adhesive portion 124 has the second surface 124a facing the isolation opening 121. On the first normal cross-section, the adhesive portion 124 extends from the sidewall 12a to the isolation opening 131 corresponding to the first end portion P in the direction away from the first end portion P, and the sidewall 12a does not include the second surface 124a. The orthographic projection of the first isolation portion 122 on the base plate 11 is located within an orthographic projection of the adhesive portion 124 on the base plate 11. In this implementation, on the first normal section, the isolation structure 12 has an I-shaped section.

The adhesion between the isolation structure 12 and the base plate 11 can be increased by adding the adhesive portion 124, which improves the stability of the isolation structure 12 on the base plate 11. Exemplarily, in this embodiment, a material of the first isolation portion 122 includes aluminum, a material of the second isolation portion 123 includes titanium, and a material of the adhesive portion 124 includes molybdenum.

Referring to FIG. 11, in this embodiment, the light-emitting material layer 132 includes a hole transport layer 1322 (HTL), an emission layer 1324 (EML), and an electron transport layer 1326 (ETL) that are stacked in sequence in a direction away from the base plate 11, one layer of the hole transport layer 1322, the emission layer 1324, and the electron transport layer 1326 has a first orthographic projection on the base plate 11, the other layers of the hole transport layer 1322, the emission layer 1324, and the electron transport layer 1326 have a second orthographic projection on the base plate 11, and the second orthographic projection is located within the first orthographic projection, i.e., an area of the second orthographic projection is less than an area of the first orthographic projection, and the third end portion M is located on the one layer. Exemplarily, under a condition that the electron transport layer 1326 is the one layer, and the hole transport layer 1322 and the emission layer 1324 are the other layers, an orthographic projection of the hole transport layer 1322 and the emission layer 1324 on the base plate 11 is located within an orthographic projection of the electron transport layer 1326 on the base plate 11, and the third end portion M is located on the electron transport layer 1326. Herein, the electron transport layer 1326 may or may not contact the sidewall 12a.

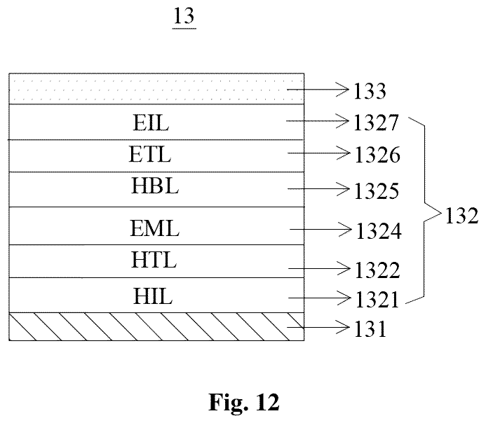

Further, referring to FIG. 12, the light-emitting material layer 132 further includes a hole injection layer 1321 (HIL), a hole block layer 1325 (HBL), and an electron injection layer 1327 (EIL). The hole injection layer 1321 is located at a side of the hole transport layer 1322 away from the emission layer 1324, i.e., the hole injection layer 1321 is located between the hole transport layer 1322 and the second electrode 133. The hole block layer 1325 is located between the emission layer 1324 and the electron transport layer 1326. The electron injection layer 1327 is located at a side of the electron transport layer 1326 away from the emission layer 1324, i.e., the electron injection layer 1327 is located between the electron transport layer 1326 and the first electrode 131.

An orthographic projection of hole injection layer 1321 on base plate 11 is located outside the orthographic projection of first isolation portion 122 on base plate 11, and/or an orthographic projection of hole transport layer 1322 on the base plate 11 is located outside the orthographic projection of the first isolation portion 122 on the base plate 11. An interval is formed between the hole injection layer 1321 and/or the hole transport layer 1322 and the first isolation portion 122, and the hole injection layer 1321 and/or the hole transport layer 1322 does not contact the first surface 122a (the sidewall 12a) of the first isolation portion 122, so as to prevent, when the hole injection layer 1321 and/or the hole transport layer 1322 are in direct contact with the first electrode 131, holes in the hole injection layer 1321 and/or the hole transport layer 1322 from being directly combined with electrons in the first electrode 131 and annihilating, which increases the light emitting power consumption of the light-emitting device 13.

In this embodiment, the hole injection layer 1321 and/or the hole transport layer 1322 do not contact the sidewall 12a, while at least one of the emission layer 1324, the hole block layer 1325, the electron transport layer 1226, and the electron injection layer 1327 may contact the sidewall 12a.

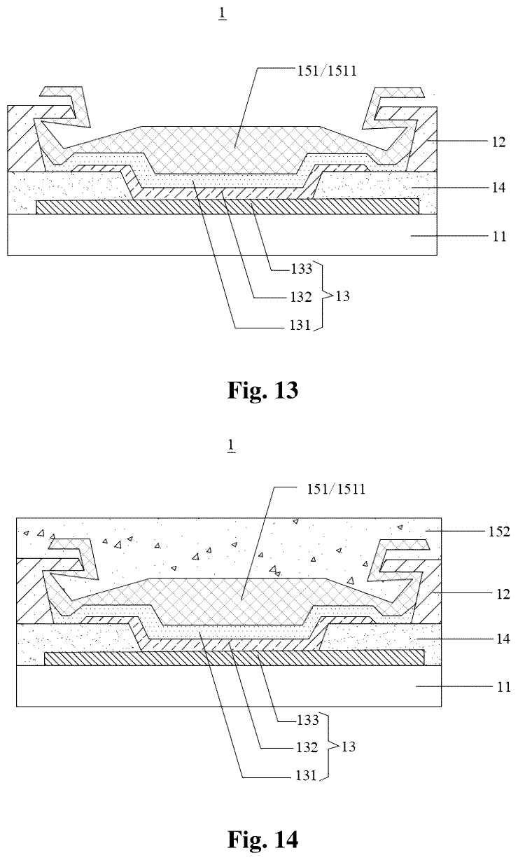

Further, referring to FIG. 13, the display panel 1 further includes a first encapsulation layer 151, the first encapsulation layer 151 is located at a side of the light-emitting device 13 away from the base plate 11, and is in contact with at least the sidewall 12a at a side of the isolation structure 12 facing the isolation opening 121. The first encapsulation layer 151 includes a plurality of encapsulation units 1511, and adjacent encapsulation units 1511 are separated at a surface of the isolation structure 12 away from the base plate 11, in which the encapsulation unit 1511 includes an inorganic material, and the encapsulation unit 1511 may be manufactured by chemical vapor deposition. Each encapsulation unit 1511 is configured to independently encapsulate a light-emitting device 13 in one isolation opening 121. In this embodiment, due to the smooth sidewall 12a at the side of the isolation structure 12 facing the isolation opening 121, the encapsulation unit 1511 can closely fit the side of the isolation structure 12 facing the isolation opening 121, so as to improve the encapsulation effect. In this embodiment, at the side of the isolation structure 12 away from the base plate 11, a gap is formed between the encapsulation unit 1511 and the isolation structure 12.

Referring to FIG. 14, the display panel 1 further includes a second encapsulation layer 152. The second encapsulation layer 152 covers at least the encapsulation unit 1511, a material of the second encapsulation layer 152 includes an organic material, the second encapsulation layer 152 may be manufactured by ink-jet printing, and the second encapsulation layer 152 may fill the isolation opening 121 and form a flat surface at a side away from the base plate 11 so as to facilitate the manufacturing of subsequent film layers. In addition, the second encapsulation layer 152 is also disposed in the gap between the encapsulation unit 1511 and the isolation structure 12.

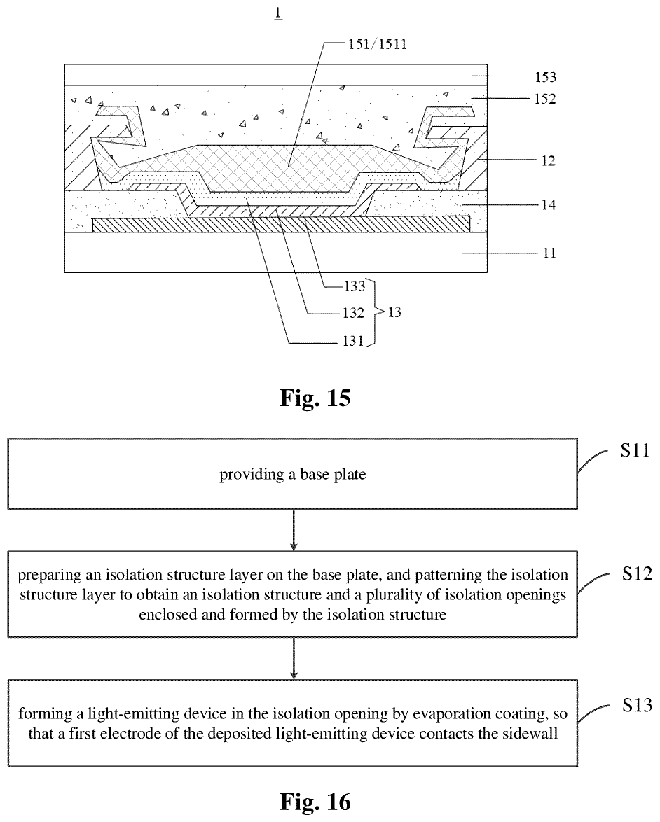

Referring to FIG. 15, the display panel 1 further includes a third encapsulation layer 153, the third encapsulation layer 153 is located at a side of the second encapsulation layer 152 away from the base plate 11, a material of the third encapsulation layer 153 includes an inorganic material, and the third encapsulation layer 153 can be manufactured by chemical vapor deposition.

The first encapsulation layer 151, the second encapsulation layer 152, and the third encapsulation layer 153 form a thin film encapsulation structure of the display panel 1.

It can be understood that the display panel 1 may further include a touch control functional layer, an optical adhesive layer, a polarizer, a cover plate, and other film layers that are stacked at a side of the third encapsulation layer 153 away from the base plate 11 in sequence, and the above film layers are conventional film layers of the display panel and are not repeated herein.

Based on the same inventive concept, the embodiments of the present application further provides a method for manufacturing a display panel, which is used for manufacturing the display panel described above. Referring to FIG. 16, the method for manufacturing the display panel includes the following steps.

Step S11, providing a base plate.

Step S12, preparing an isolation structure layer on the base plate, and patterning the isolation structure layer to obtain an isolation structure and a plurality of isolation openings enclosed and formed by the isolation structure.

The isolation structure has a sidewall facing the isolation opening, and a first angle α is formed between the sidewall and the base plate.

Step S13, forming a light-emitting device in the isolation opening by evaporation, to contact a first electrode of the light-emitting device with the sidewall.

The first angle α is less than a complementary angle of an evaporation angle of the first electrode. With further reference to FIG. 1, the first electrode 131 has a first end portion P, the isolation structure 12 has a second end portion Q, and the second end portion Q extends from the sidewall 12a to an isolation opening corresponding to the first end portion P in a direction away from the first end portion P. The first end portion P and the second end portion Q are located at the same side of the same isolation opening 121, a second angle θ is formed between the base plate 11 and a connecting line L1 from the first end portion P to the second end portion Q, and the second angle θ is equal to the evaporation angle of the first electrode 131, i.e., the first angle α is less than (90−θ).

In this embodiment, the light-emitting device further includes a light-emitting material layer. In one possible implementation, step S13 further includes evaporating the light-emitting material layer before evaporating the first electrode, in which an evaporation angle of the light-emitting material layer is greater than the evaporation angle of the first electrode. With further reference to FIG. 4, on the first normal section of the display panel, the light-emitting material layer 132 has a third end portion M, the third end portion M is close to the first end portion, a third angle β is formed between the base plate 11 and a connecting line L2 from the third end portion M to the second end portion Q, and the third angle β is equal to the evaporation angle of the light-emitting material layer 132.

Based on the same inventive concept, the embodiments of the present application further provides an electronic device, and the electronic device may include the display panel described in the above embodiments. Exemplarily, the electronic device may include a smart phone, a tablet computer, a television, etc. The second electrode in the above display panel may effectively contact the contact side surface of the isolation structure, so that the dark spot or the black spot may be reduced, which is beneficial for the improvement of the display effect of the display apparatus, thereby improving the market competitiveness of the display apparatus.

The embodiments of the present application provide the display panel and the electronic device. In the display panel, the isolation structure has a sidewall facing the isolation opening, a first angle is formed between the sidewall and the base plate, the first electrode of the light-emitting device contacts the sidewall, the first electrode includes a first end portion, the isolation structure includes a second end portion, the second end portion extends from the sidewall to an isolation opening corresponding to the first end portion in a direction away from the first end portion, a second angle is formed between the base plate and a connecting line from the first end portion to the second end portion, and the first angle is less than a complementary angle of the second angle. The above design can avoid the situation of the minimum coverage area of the first electrode on the sidewall, so as to increase the contact area of the first electrode on the sidewall, which ensures the contact effect of the first electrode, thereby improving the product yield of the display panel.

While the foregoing is directed to the preferred embodiments of the present invention, other and further embodiments of the invention may be devised without departing from the basic scope thereof, and the scope thereof is determined by the claims that follow. Any modification, equivalent replacement and improvement made within the spirit and principle of the present application shall be included in the protection scope of the present application.

What is claimed is:

1. A display panel, comprising:
a base plate;
an isolation structure, the isolation structure being located on the base plate, enclosing and forming a plurality of isolation openings, and having a sidewall facing the isolation opening, and a first angle being formed between the sidewall and the base plate;
a plurality of light-emitting devices, the light-emitting device being located in the isolation opening and comprising a first electrode contacted with the sidewall;
wherein on a first normal section of the display panel, the first electrode comprises a first end portion, the isolation structure comprises a second end portion, the second end portion extends from the sidewall to an isolation opening corresponding to the first end portion in a direction away from the first end portion, a second angle is formed between the base plate and a connecting line from the first end portion to the second end portion, and the first angle is less than a complementary angle of the second angle.

2. The display panel according to claim 1, wherein the light-emitting device further comprises:
a light-emitting material layer located at a side of the first electrode facing the base plate;
wherein on the first normal section, the light-emitting material layer comprises a third end portion close to the first end portion, a third angle is formed between the base plate and a connecting line from the third end portion to the second end portion, and the third angle is greater than the second angle;
the light-emitting material layer contacts the sidewall;
an interval is formed between the light-emitting material layer and the sidewall.

3. The display panel according to claim 1, wherein the isolation structure comprises:
a first isolation portion, wherein the first isolation portion has a first surface facing the isolation opening and located in the sidewall;
a second isolation portion, wherein the second isolation portion is located at a side of the first isolation portion away from the base plate, an orthographic projection of the first isolation portion on the base plate is located within an orthographic projection of the second isolation portion on the base plate;
the second end portion is located on the second isolation portion.

4. The display panel according to claim 3, wherein the isolation structure further comprises an adhesive portion, the adhesive portion is located at a side of the first isolation portion facing the base plate, and the adhesive portion has a second surface facing the isolation opening;
the first surface and the second surface are coplanar and located in the sidewall; or on the first normal section, the adhesive portion extends from the sidewall to the isolation opening corresponding to the first end portion in the direction away from the first end portion, and the second surface does not located in the sidewall; and the orthographic projection of the first isolation portion on the base plate is located within an orthographic projection of the adhesive portion on the base plate;
a material of the first isolation portion comprises aluminium, a material of the second isolation portion comprises titanium, and a material of the adhesive portion comprises molybdenum.

5. The display panel according to claim 1, wherein a first perpendicular distance is formed between the first end portion and the base plate, a second perpendicular distance is formed between the second end portion and the base plate, and the first perpendicular distance is less than the second perpendicular distance.

6. The display panel according to claim 2, wherein a first perpendicular distance is formed between the first end portion and the base plate, a third perpendicular distance is formed between the third end portion and the base plate, and the first perpendicular distance is greater than the third perpendicular distance.

7. The display panel according to claim 2, wherein on the first normal section, the first end portion extends a first length on the sidewall, the third end portion extends a second length on the sidewall, and the first length is greater than the second length.

8. The display panel according to claim 1, wherein the first angle is greater than 0 degrees, and the first angle is less than 90 degrees; and
the first angle is not less than 30 degrees, and the first angle is not greater than 80 degrees.

9. The display panel according to claim 2, wherein the light-emitting material layer comprises a hole transport layer, an emission layer, and an electron transport layer that are stacked in sequence in a direction away from the base plate, wherein:
one layer of the hole transport layer, the emission layer, and the electron transport layer has a first orthographic projection on the base plate, the other layers of the hole transport layer, the emission layer, and the electron transport layer have a second orthographic projection on the base plate, and the second orthographic projection is located within the first orthographic projection; and
the third end portion is located on the one layer.

10. The display panel according to claim 9, wherein the electron transport layer is the one layer, and the hole transport layer and the emission layer are the other layers; and
an orthographic projection of the hole transport layer and the emission layer on the base plate is located within an orthographic projection of the electron transport layer on the base plate.

11. The display panel according to claim 9, wherein the light-emitting material layer further comprises:
a hole injection layer located at a side of the hole transport layer away from the emission layer;
a hole block layer located between the emission layer and the electron transport layer;
an electron injection layer located at a side of the electron transport layer away from the emission layer; wherein
the isolation structure comprises a first isolation portion and a second isolation portion, the second isolation portion is located at a side of the first isolation portion away from the base plate, and an orthographic projection of the first isolation portion on the base plate is located within an orthographic projection of the second isolation portion on the base plate, wherein:
an orthographic projection of the hole injection layer on the base plate is located outside the orthographic projection of the first isolation portion on the base plate, and/or an orthographic projection of the hole transport layer on the base plate is located outside the orthographic projection of the first isolation portion on the base plate; and
at least one of the emission layer, the hole block layer, the electron transport layer, and the electron injection layer contacts the sidewall.

12. The display panel according to claim 1, further comprising:
a pixel definition layer located at one side of the base plate, wherein the pixel definition layer encloses and forms a plurality of pixel openings, and the light-emitting device is at least partially located in the pixel opening;
the isolation structure is located at a side of the pixel definition layer away from the base plate, the isolation opening is connected with a pixel opening corresponding to the isolation opening, and an orthographic projection of the pixel opening on the base plate is located within an orthographic projection of the isolation opening on the base plate.

13. The display panel according to claim 12, wherein the light-emitting device further comprises:
a second electrode located at a side of the first electrode facing the base plate;
wherein on the first normal section, the second electrode has a fourth end portion extending towards the first end portion, and the fourth end portion is located between the pixel definition layer and the base plate.

14. The display panel according to claim 13, wherein the isolation structure comprises a first isolation portion and a second isolation portion, the second isolation portion is located at a side of the first isolation portion away from the base plate, and an orthographic projection of the first isolation portion on the base plate is located within an orthographic projection of the second isolation portion on the base plate, wherein:
an orthographic projection of the fourth end portion on the base plate is located within the orthographic projection of the first isolation portion on the base plate.

15. The display panel according to claim 1, further comprising a first encapsulation layer;
wherein the first encapsulation layer comprises a plurality of encapsulation units, each of the encapsulation units are configured to encapsulate a corresponding one of the light-emitting devices disposed in an isolation opening of the isolation openings, and two adjacent encapsulation units are disconnected at a side of the isolation structure away from the base plate; and
at the side of the isolation structure away from the base plate, a gap is formed between the encapsulation unit and the isolation structure.

16. The display panel according to claim 15, further comprising a second encapsulation layer;
wherein the second encapsulation layer is located at a side of the first encapsulation layer away from the base plate, and the second encapsulation layer covers at least the first encapsulation layer;
the second encapsulation layer is disposed in the gap between the encapsulation unit and the isolation structure;
the second encapsulation layer has a flat surface at a side away from the base plate;
the display panel further comprises a third encapsulation layer, and the third encapsulation layer is located at a side of the second encapsulation layer away from the base plate; and
the first encapsulation layer and the third encapsulation layer are inorganic encapsulation layers, and the second encapsulation layer is an organic encapsulation layer.

17. A method for manufacturing a display panel, comprising:
providing a base plate;
preparing an isolation structure layer on the base plate, and patterning the isolation structure layer to obtain an isolation structure and a plurality of isolation openings enclosed and formed by the isolation structure, wherein the isolation structure has a sidewall facing the isolation opening, and a first angle is formed between the sidewall and the base plate; and
forming a light-emitting device in the isolation opening by evaporation, to contact a first electrode of the light-emitting device with the sidewall, wherein the first angle is less than a complementary angle of an evaporation angle of the first electrode.

18. The method for manufacturing the display panel according to claim 17, wherein on a first normal section of the display panel, the first electrode has a first end portion, the isolation structure has a second end portion, the second end portion extends from the sidewall to an isolation opening corresponding to the first end portion in a direction away from the first end portion, a second angle is formed between the base plate and a connecting line from the first end portion to the second end portion, and the second angle is equal to the evaporation angle of the first electrode.

19. The method for manufacturing the display panel according to claim 18, wherein the light-emitting device further comprises a light-emitting material layer, and forming the light-emitting device in the isolation opening by evaporation further comprises:
evaporating the light-emitting material layer before evaporating the first electrode, wherein an evaporation angle of the light-emitting material layer is greater than the evaporation angle of the first electrode;
on the first normal section of the display panel, the light-emitting material layer has a third end portion, the third end portion is close to the first end portion, a third angle is formed between the base plate and a connecting line from the third end portion to the second end portion, and the third angle is equal to the evaporation angle of the light-emitting material layer.
